(19) United States
(12) Patent Application Publication
(10) Pub. No.: US 2003/0058045 A1
(43) Pub. Date: Mar. 27, 2003

(54) Power control in RF amplifiers

(76) Inventors: Stewart Sidney Taylor, Beaverton, OR (US); Carlton Stuebing, The Dalles, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/962,688

(22) Filed: Sep. 25, 2001

(51) Int. Cl. H03G 3/20

(52) U.S. Cl. 330/133

(57) ABSTRACT

Method and apparatus for power control in an RF amplifier having reduced noise and moderate gain slope. In one embodiment, a multistage RF amplifier includes a first stage having a transconductance amplifier with an output coupled to a variable gain amplifier, with the gain control including control of the collector-emitter voltage of the output transistor of the variable gain amplifier. In another embodiment, the variable gain amplifier is replaced with a single transistor, with the gain control including control of the collector-emitter voltage of the single transistor. Reduction of the collector-emitter voltage followed by a reduction in the base-emitter voltage of the second stage for reduced gain of the amplifier reduces noise in the amplifier output for reduced gains, typically providing a monotonically decreasing noise with gain reduction.

### BACKGROUND OF THE INVENTION

1. Field of the Invention

The present invention pertains to power amplifiers and in particular to methods and apparatus for power control of radio-frequency (RF) power amplifiers.

2. Prior Art

RF power amplifiers are used in many applications, including portable communication devices for transmitting analog and digital information. In many applications, the RF broadcast power provided by such portable devices is controlled by the base station based upon the strength of the signals received by the base station from the portable devices. Accordingly, RF amplifiers in such devices need to be able to transmit the maximum RF power required for such a device when necessary, yet transmit RF signals at lower power levels when applicable, to transmit such RF signals efficiently with low noise, and to provide a well behaved, monotonic gain control capability for the amplifier. Accordingly, variable gain power amplifier systems are generally required for these, as well as other uses.

Some prior art circuits use multistage common emitter amplifiers wherein the base voltage for each stage is varied for low gain, and gain control for increasing gain is achieved by increasing the base voltage to the output stage, then increasing the base voltage of stage 2, and finally increasing the base voltage in the input stage. This technique is useful, though generates more noise in the transmitted signal and has a greater gain slope than does the present invention.

### BRIEF SUMMARY OF THE INVENTION

Method and apparatus for power control in an RF amplifier having reduced noise and moderate gain slope. In one embodiment, a multistage RF amplifier includes a first stage having a transconductance amplifier with an output coupled to a variable gain amplifier, with the gain control including control of the collector-emitter voltage of the output transistor of the variable gain amplifier. In another embodiment, the variable gain amplifier is replaced with a single transistor, with the gain control including control of the collector-emitter voltage of the single transistor. Reduction of the collector-emitter voltage followed by a reduction in the base-emitter voltage of the second stage for reduced gain of the amplifier reduces noise in the amplifier output for reduced gains, typically providing a monotonically decreasing noise with gain reduction.

### BRIEF DESCRIPTION OF THE DRAWINGS

FIG. 1 is a circuit diagram for an exemplary three-stage RF power amplifier in which the present invention may be practiced.

FIG. 2 illustrates a preferred variation of various control parameters of the amplifier of FIG. 1 with the control voltage V_{X}.

FIG. 3 illustrates the resulting output power Pₒ, amplifier efficiency and gain slope versus the control voltage V_{X} for the amplifier of FIG. 1 as controlled as shown in FIG. 2.

FIG. 4 is a circuit diagram for an alternate embodiment amplifier in which the present invention may be practiced.

FIG. 5 illustrates a preferred variation of various control parameters of the amplifier of FIG. 4 with the control voltage V_{X}.

FIG. 6 is a circuit diagram for a further alternate embodiment amplifier in which the present invention may be practiced.

### DETAILED DESCRIPTION OF THE PREFERRED EMBODIMENT

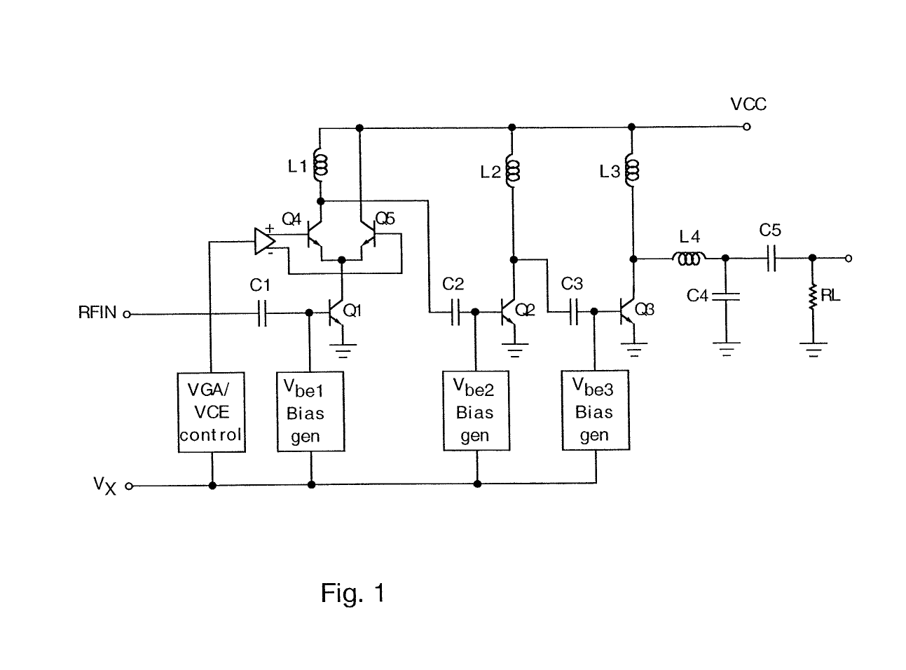

First referring to FIG. 1, an exemplary amplifier in which the present invention may be practiced may be seen. This amplifier is well suited for use in RF applications such as power amplifiers for cell phones and other mobile RF equipment, though its use is not so limited. The embodiment of FIG. 1 comprises three transconductance amplifiers, namely transistors Q1, Q2 and Q3, with common emitter coupled transistors Q4 and Q5 providing a variable gain amplifier (VGA) or current steering circuit for control of the coupling of the output of transconductance amplifier Q1 to the input of transconductance amplifier Q2. Transconductance amplifier comprising transistor Q1 together with the VGA is sometimes referred to herein as stage 1, transconductance amplifier comprising transistor Q2 is sometimes referred to herein as stage 2 and transconductance amplifier comprising transistor Q3 is sometimes referred to herein as stage 3.

Coupling capacitors C1, C2 and C3 couple the RF input signal RFIN to the first transconductance amplifier (transistor Q1), the output of the variable gain amplifier (transistors Q4 and Q5) to the second transconductance amplifier (transistor Q2) and the output of the second transconductance amplifier to the input of the third transconductance amplifier (transistor Q3), respectively. The variable gain amplifier comprising transistors Q4 and Q5 is controlled through the VGA/VCE control by the control voltage V_{X}. The VGA/VCE control controls both the differential input (VGA) to the differential variable gain amplifier to control its gain, and the common-mode input (VCE) to the differential amplifier to control the collector-emitter voltage of transistor Q4, the collector-emitter voltage of transistor Q4 being one VBE (base-emitter voltage) below the common-mode input voltage to the transistors Q4 and Q5. In the preferred embodiment, these are independent controls in the sense that the function of the VGA control versus V_{X} is a different function than the function of the VCE control versus V_{X}.

Inductor L1 provides DC current to the collector of transistor Q4 and impedance matching between stages 1 and 2. Similarly, inductors L2 and L3 provide collector currents to transconductance amplifiers Q2 and Q3, respectively, and impedance matching between the respective stages. Alternatively inductor L3 may be a choke. Inductor L4, together with capacitor C4, provides impedance matching for the amplifier output, with capacitor C5 coupling the voltage on the junction between inductor L4 and capacitor C4 to the output load RL.

DC biasing of an amplifier such as that shown in FIG. 1 is particularly important, as the biasing affects the performance of the amplifier in terms of noise and efficiency, both being important considerations in battery powered mobile communications equipment. In general, it is necessary that the overall gain of the power amplifier be a well behaved monotonic function of a gain control signal. In FIG. 1, it is not necessary for the gain control signal V_{X} to be any specific function, such as linear with respect to the control signal, logarithmic with respect to the control signal, etc., provided the gain variation with gain control signal has a reasonable slope over the desired gain control range.

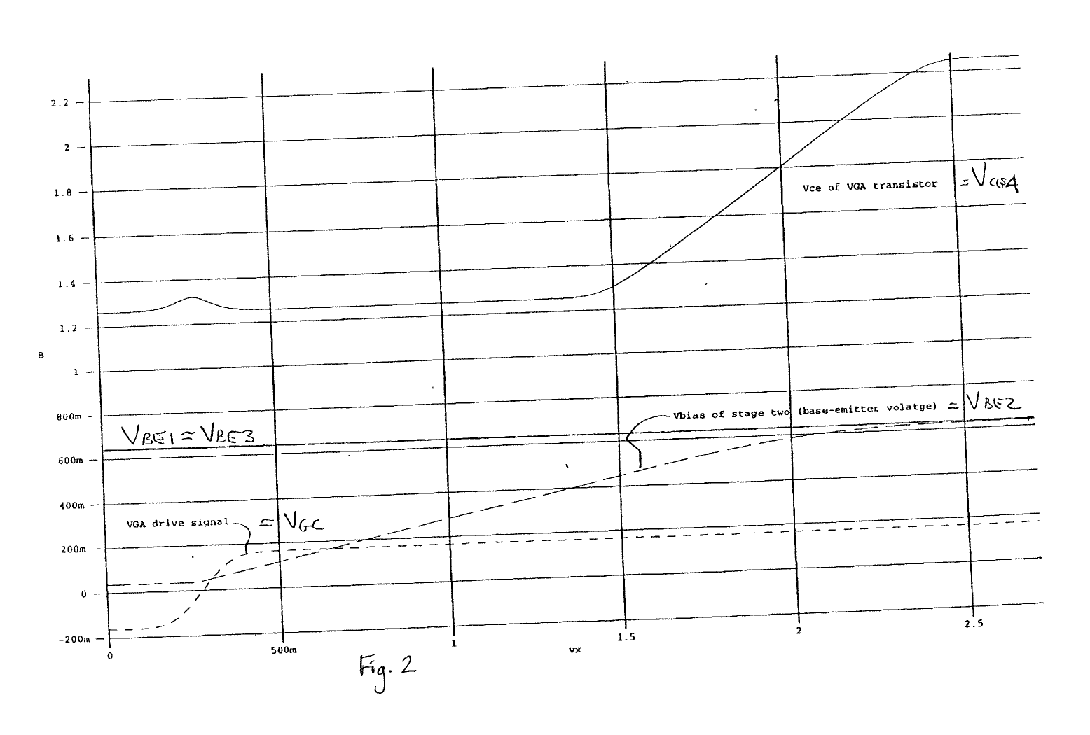

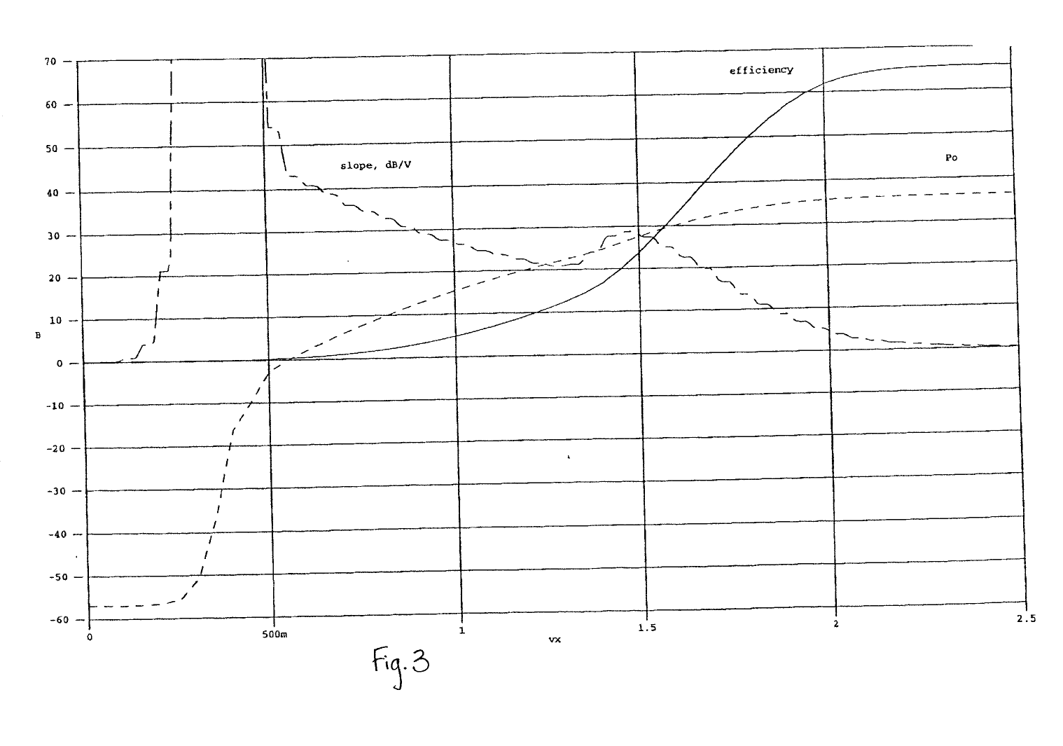

Referring now to FIGS. 1, 2 and 3, the control of the gain of the amplifier of FIG. 1 will be described. FIG. 2 illustrates the variation of various parameters (DC values) with the control voltage V_{X}, and FIG. 3 illustrates the resulting output power Pₒ (in dBm), the amplifier efficiency (in percentage) and the gain slope (dB/volt) versus the control voltage V_{X} (in volts).

Of particular importance to the present invention is the control of an amplifier such as the amplifier of FIG. 1 as illustrated in FIGS. 2 and 3 for control voltages V_{X} of about 500 millivolts and above. In that regard, a control voltage of 500 millivolts for this exemplary embodiment corresponds to a low gain in the normal gain control range. As may be seen in FIG. 2, in this embodiment, for values of V_{X} of 500 millivolts and above, the differential amplifier (VGA) control signal remains near 200 millivolts, holding transistor Q4 on and transistor Q5 off. As the value of V_{X} goes substantially below 500 millivolts, the VGA control signal reverses, turning transistor Q4 off and transistor Q5 on, essentially diverting the entire RF signal to the power supply terminal for isolation purposes. Thus the VGA in this exemplary embodiment is not part of the normal operating gain control of the amplifier, described below.

In the description to follow, V_{ben} represents the base-emitter voltage of a respective transistor n, such as V_{be1}, V_{be2}, etc. for transistors Q1, Q2 etc. The exemplary embodiment of the present invention illustrated in FIGS. 1, 2 and 3 achieves improved noise performance. These Figures illustrate a preferred variation of the various control parameters with the control voltage V_{X} at one temperature. At minimum output power, typically −10 dBm, the nominal base bias voltage V_{be3} and V_{be1} (and therefore collector currents) for the output stage transistor Q3 and the input stage transistor Q1 are established, the collector-to-emitter voltage of the transistor Q4 (or common-base stage) of the input stage is set one volt or more below its nominal value, and the base bias voltage V_{be2} of the second stage is set to a small value, typically 50 mV. Output power is increased by first increasing the bias voltage V_{BE2} to the base of stage two. Then the collector-to-emitter voltage of the VGA (common-base stage comprising transistors Q4 and Q5) of the input stage is increased, typically by one volt or more. It is possible that the last 100-200 mV of increase in the bias voltage V_{BE2} to the base of stage two will occur while the collector-to-emitter voltage of the VGA transistors is being increased. Generally, the output noise remains relatively constant or decreases with decreasing output power with this arrangement. This results from gain compression at the output of stage 1. The output noise power is typically 3-5 dB lower than with a more conventional arrangement that establishes stage three base-emitter bias, then increases stage two base-emitter bias, and finally increases stage one base-emitter bias (for this arrangement, the collector-emitter voltage of all stages is constant at their nominal values).

The maximum slope of output power versus control voltage is managed by arranging the rate at which the bias voltages are varied. Typically, the collector-to-emitter voltage of the VGA (or common base stage) is increased approximately linearly by one volt or so as the power control voltage (V_{X}) is increased by one volt (typically from 1.4V to 2.4V), and the bias voltage V_{be2} on the base of the second stage is increased approximately linearly by 600 mV (typically from 50 mV to 650 mV) as the power control voltage is increased by one and one half to two volts (typically from 0.5V to 2V). A slope of less that 50 dB per volt is typically achieved. This embodiment maintains a relatively low and constant VSWR (voltage standing wave ratio) at the input because the bias voltage and current of the input stage is relatively constant.

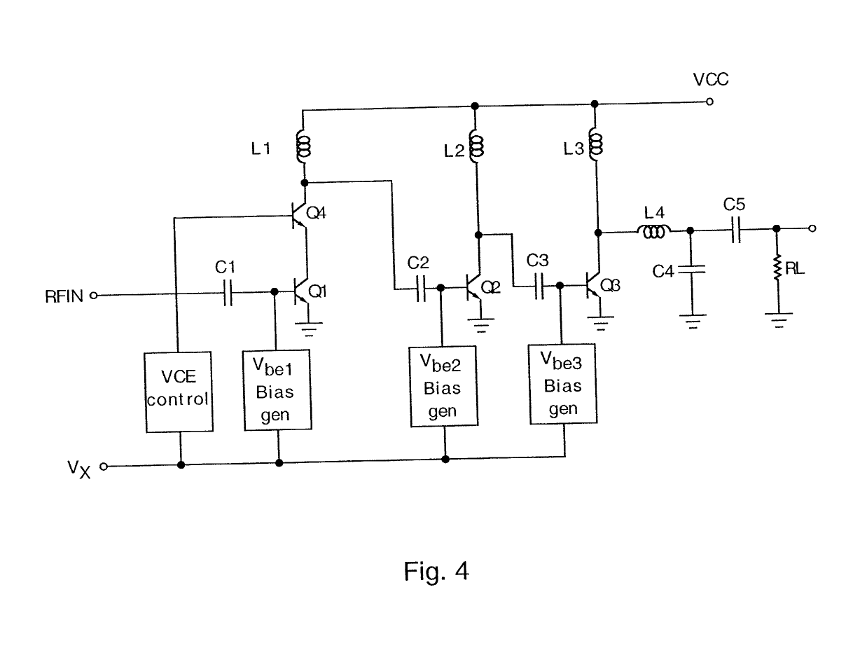

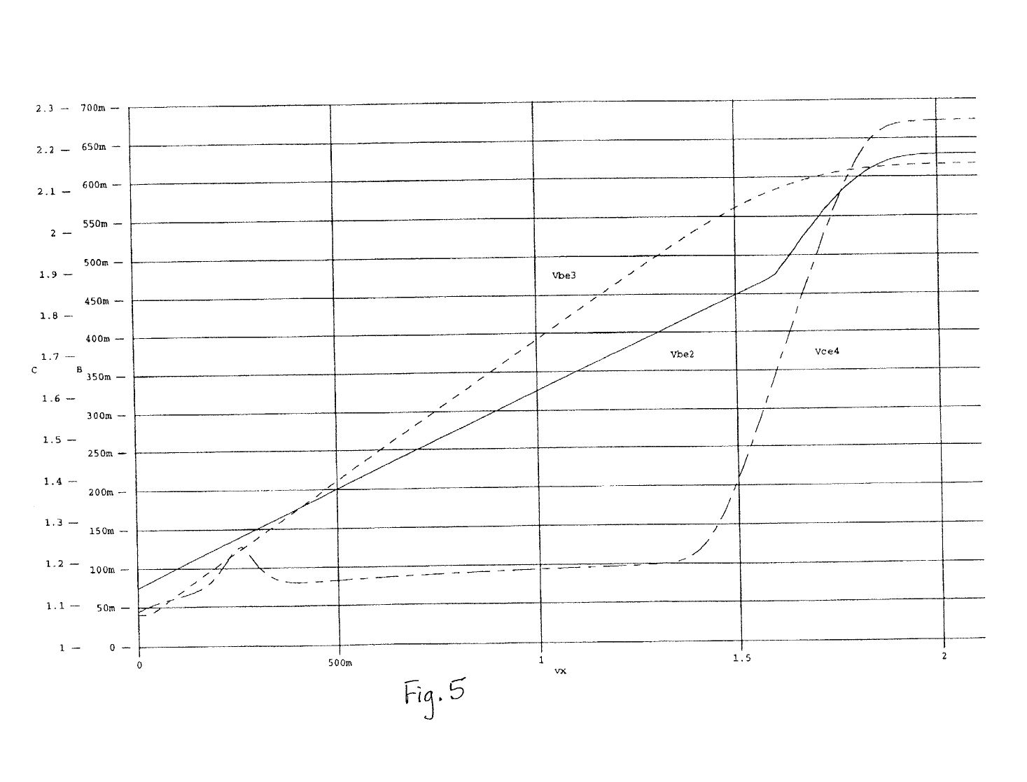

An alternate embodiment amplifier is shown in FIG. 4. In this embodiment, the differential amplifier VGA is replaced by a single transistor Q4. The preferred variation of the various control parameters with the control voltage V_{X} may be seen in FIG. 5. For a low gain, a nominal bias voltage V_{be1} is set for transistor Q1 to set the current in the first stage. The second and third stage biases V_{be2} and V_{be3} and the collector-to-emitter voltage V_{CE4} are set as shown in FIG. 5, which are increased with the control voltage V_{X} as shown. In this arrangement, the power is controlled for values of V_{X} between 0 and 2.0 volts. The minimum output power for V_{X}=0.5 volts is less than −5 dBm.

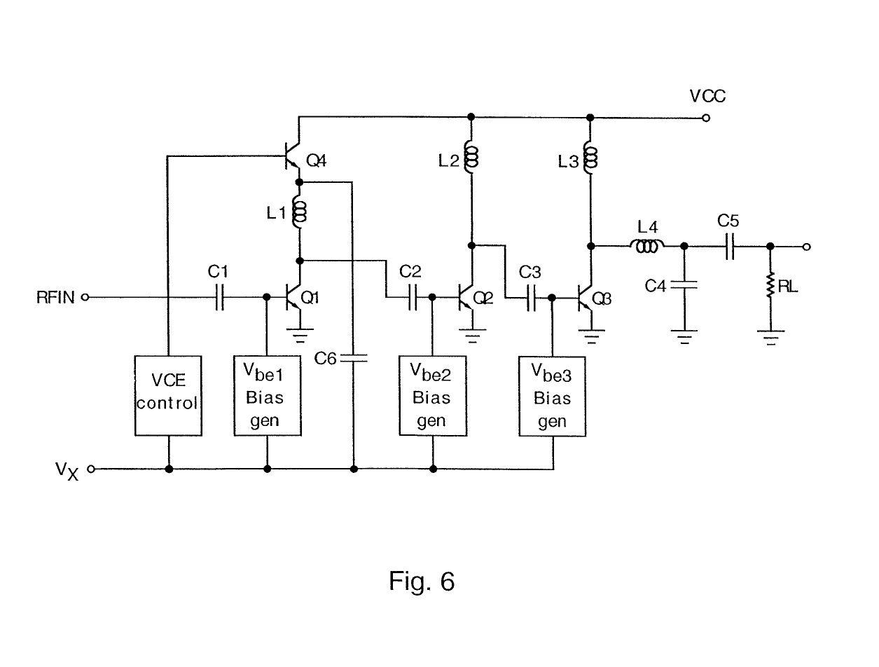

A further alternate embodiment is shown in FIG. 6. Rather than varying V_{CE} of transistor Q4 in the embodiments of FIGS. 1 and 4, the power supply voltage for the first stage may be varied (reduced for reduced gains). While a separate, controllable power supply may not be cost effective, a similar effect may be achieved by moving transistor Q4 to above inductor L1 and providing an RF bypass capacitor C6 to ground, as shown in FIG. 6. In this embodiment, the low impedance of the RF bypass capacitor at RF frequencies together with the control of the DC base voltage of transistor Q4 are substantially equivalent to varying the power supply voltage for the first stage. In the embodiments of FIGS. 1 and 4, controlling the collector-emitter voltage V_{CE4} of transistor Q4 limited the output swing of the first stage. In the embodiment of FIG. 6, the output swing of the first stage is now dependent on the collector-emitter voltage V_{CE1} of transistor Q1. Thus the embodiment of FIG. 6 will perform similarly to the embodiments of FIGS. 1 and 4 if the collector-emitter voltage V_{CE1} of transistor Q1 is varied with gain in substantially the same way that the collector-emitter voltage V_{CE4} of transistor Q4 was varied with gain for the earlier embodiments. Of course to vary the collector-emitter voltage V_{CE1} of transistor Q1 as desired, the VCE control should be configured to provide the desired VCE plus one V_{BE}, namely the V_{BE} of transistor Q4.

In the embodiments operated as illustrated in FIGS. 3 and 5, as well as other embodiments, the various control parameters, such as V_{CE}, V_{be2} and V_{be3} are varied with temperature to maintain the desired power control characteristics of the RF amplifier. In general this variation with temperature approximately tracks the variation of a V_{BE} itself with temperature, though additional shaping with temperature may be made for such purposes as to better accommodate the desired performance of the amplifier or to simplify the bias generating circuitry.

In any embodiment of the present invention described so far, a key aspect of the invention is the controlled increase in the collector-to-emitter voltage of transistor Q4 (or Q1) for increasing gains at the upper gain region of the amplifier, or stated differently, the reduction of the collector-to-emitter voltage of transistor Q4 (or Q1) for reduced gains. The specific variation of the amplifier control parameters with the gain control signal illustrated herein for the embodiments disclosed is exemplary only, as other variations may also be employed as desired, provided appropriate variation of the collector-to-emitter voltages with gain variation are employed. The net effect of the gain control is to typically achieve a monotonic reduction in noise with reduced gain. This is to be compared with the prior art gain control techniques wherein the gain of multistage amplifiers of the general type described is controlled by simply controlling the base-emitter voltages, typically for increasing gain, by first increasing the bias of stage 2 and then increasing the bias of stage 1, which amplifiers typically exhibit an initial increase in noise as gain is initially reduced before reducing with greater reduction in gain and greater noise generally. Prior art gain control techniques have a greater gain slope, typically 150 to 400 dB/volt

It will be noted that the typical variation in each of the amplifier gain control parameters with the gain control signal V_{X} used with the present invention, exemplary variations being shown in FIGS. 3 and 5 herein, are or may generally be monotonically varying parameters, easily generated using conventional interface circuit design techniques, such as by using amplifiers and passive elements for providing the desired shape in the transfer function between V_{X} and each desired control parameter. Consequently detailed circuits for the VGA/VCE control, V_{be1} bias generator and V_{be2} bias generator are not presented herein, as their detailed design is a matter of choice clearly within the skill of one of reasonable skill in the art.

The embodiments described so far have been described in relation to the use of bipolar transistors, though the invention is not so limited. While bipolar transistors, and particularly heterojunction transistors are preferred, other types of amplifying devices, such as field effect transistors (FETs), may be used. Thus the invention is applicable in a general sense to three terminal amplifying devices wherein the conduction between first and second device terminals is responsive to the voltage between a control terminal on the device and the first terminal of the device. In this case, the voltage between the control terminal and the first terminal for a bipolar device is VBE, and the voltage between the second terminal and the first terminal for a bipolar device is V_{CE.} Also of course, devices of either conductivity type may be used as desired (npn or pnp in the case of bipolar transistors, or n-channel or p-channel in the case of FETs). In the case of FETs, the base-emitter voltage of a bipolar transistor becomes the gate-source voltage of the FET, and the collector-emitter voltage of the bipolar transistor becomes the drain-source voltage of the FET. Also, reducing the V_{CE} of the device providing the output voltage of the first stage (transistor Q4 in the embodiments of FIGS. 1 and 4, and transistor Q1 in the embodiment of FIG. 6) reduces the peak to peak output of the first stage, a sort of clipping or compression of the output, providing a more rectangular output waveform for this stage. Thus in the general case of a three terminal amplifying device, the peak to peak output voltage of the first stage for maximum gain is set at a predetermined limit, and reduced when gain is reduced for better noise performance.

FIGS. 2 and 5 show exemplary voltage variations in response to the control voltage V_{X} to obtain the desired gain variations. In the more general case of a three terminal amplifying device, these voltages will change, depending on the conduction characteristics, particularly the turn-on characteristics of the devices used. In any event, in the more general sense, at full power, stages two and three will typically operate as class B amplifiers or slightly into class C operation. The first stage at full power (gain) will typically operate as a class A, or more likely as a class AB or B amplifier, with the voltage between the first and second terminals of Q4 (or Q1 of the equivalent of FIG. 6) being at a maxim. As power (gain) is reduced, stages two and three will move more into class C operation, and the voltage between the first and second terminals of Q4 (or Q1) will be reduced. Of course the opposite is true for increasing gain, the settings for each gain level being independent of the direction of the gain change to get to that gain setting.

While certain exemplary embodiments of the present invention have been described in detail and shown in the accompanying drawings, it is to be understood that such embodiment is merely illustrative of and not restrictive on the broad invention, and that this invention is not to be limited to the specific arrangements, constructions and methods shown and described, but instead is to be defined by the full scope of the following claims, since various other modifications will occur to those of ordinary skill in the art.

What is claimed is:

1. A method of increasing the power output of an amplifier from a low power output, the amplifier having at least first and second stages having first and second amplifying devices, respectively, the first stage being coupled to the second stage through a third amplifying device, each amplifying device having first and second terminals and a control terminal, the conduction between the first and second terminals being responsive to the voltage on the control terminal relative to the first terminal, the second terminal of the first amplifying device being coupled to the first terminal of the third amplifying device and the second terminal of the third amplifying device being coupled to the control terminal of the second amplifying device, comprising:
increasing the DC voltage on the control terminal of the second amplifying device; and,
increasing the DC voltage between the first and second terminals of the third amplifying device by changing the DC voltage on the control terminal of the third amplifying device.

2. The method of claim 1 wherein the increase in the DC voltage between the first and second terminals of the third amplifying device overlaps the increase in the DC voltage on the control terminal of the second amplifying device.

3. The method of claim 2 wherein the amplifier includes a third stage including a fourth amplifying device having its control terminal coupled to the second amplifying device, the method further comprising increasing the DC voltage on the control terminal of the fourth transistor as the DC voltage on the control terminal of the second transistor is increased.

4. The method of claim 3 wherein the third transistor is one of a pair of transistors forming a variable gain amplifier, the DC voltage on the control terminal of the third transistor being changed by changing the common mode voltage input to the variable gain amplifier.

5. A method of increasing the power output of an amplifier from a low power output, the amplifier having at least first, second and third stages having first, second and third transistors, respectively, the first stage being coupled to the second stage through a fourth transistor, each transistor having first and second terminals and a control terminal, the conduction between the first and second terminals being responsive to the voltage of the control terminal relative to the first terminal, the second terminal of the first transistor being coupled to the first terminal of the fourth transistor and the second terminal of the fourth transistor being coupled to the control terminal of the second transistor, comprising:
increasing the DC voltage on the control terminal of the second transistor; and,
increasing the DC voltage between the first and second terminals of the third transistor by changing the DC voltage on the control terminal of the third transistor.

6. The method of claim 5 wherein the increase in the DC voltage between the first and second terminals of the third transistor overlaps the increase in the DC voltage on the control terminal of the second transistor.

7. The method of claim 5 further comprised of increasing the DC voltage on the control terminal of the third transistor as the DC voltage on the control terminal of the second transistor is increased.

8. The method of claim 7 wherein the increase in the DC voltage between the first and second terminals of the third transistor overlaps the increase in the DC voltage on the control terminals of the second and third transistors.

9. The method of claim 5 wherein the fourth transistor is one of a pair of transistors forming a variable gain amplifier, the DC voltage on the control terminal of the third transistor being changed by changing the common mode voltage input to the variable gain amplifier.

10. A method of increasing the power output of an amplifier from a low power output, the amplifier having at least first and second stages having first and second amplifying devices, respectively, each amplifying device having first and second terminals and a control terminal, the conduction between the first and second terminals being responsive to the voltage on the control terminal relative to the first terminal, the second terminal of the first amplifying device being coupled to the control terminal of the second amplifying device, comprising:
increasing the DC voltage on the control terminal of the second amplifying device; and,
increasing the DC voltage on the second terminal of the first amplifying device.

11. The method of claim 10 wherein the increase in the DC voltage on second terminal of the first amplifying device overlaps the increase in the DC voltage on the control terminal of the second amplifying device.

12. The method of claim 11 wherein the amplifier includes a third stage including a third amplifying device having its control terminal coupled to the second terminal of the second amplifying device, the method further comprising increasing the DC voltage on the control terminal of the third transistor as the voltage on the control terminal of the second transistor is increased.

13. A method of controlling the gain in a multi-stage amplifier having at least first and second stages, each stage having an amplifying device, comprising:
for maximum gain;
a) operating the first stage as a class A, AB or B amplifier,
b) operating the second stage as a class B or slightly class C amplifier,
c) limiting the peak to peak voltage output of the first stage to a predetermined voltage, and for reducing the gain;
d) reducing the limit on the peak to peak voltage output of the first stage, and
e) changing the bias of the second stage so that the second stage operates more into class C.

14. The method of claim 13 wherein reducing the limit on the peak to peak voltage output of the first stage overlaps the changing of the bias of the second stage so that the second stage operates more into class C.

15. The method of claim 14 wherein the amplifier includes a third stage including a third amplifying device, the method further comprising, for reducing the gain, decreasing the DC voltage on the control terminal of the fourth transistor as the DC voltage on the control terminal of the second transistor is decreased.
